(19) United States
(12) Patent Application Publication
(10) Pub. No.: US 2012/0327588 A1
(43) Pub. Date: Dec. 27, 2012

(54) MOUNTING APPARATUS FOR DATA STORAGE DEVICE

(75) Inventors: CHAO GENG, Wuhan City (CN); QIU-HUA BIN, Wuhan City (CN); XIANG ZHANG, Wuhan City (CN)

(73) Assignees: HON HAI PRECISION INDUSTRY CO., LTD., Tu-Cheng (TW); HONG FU JIN PRECISION INDUSTRY (Wuhan) CO., LTD., Wuhan City (CN)

(21) Appl. No.: 13/438,015

(22) Filed: Apr. 3, 2012

(30) Foreign Application Priority Data
Jun. 24, 2011 (CN) 201110172976.3

(51) Int. Cl. G06F 1/16; H05K 7/14

(52) U.S. Cl. 361/679.39; 248/221.11

(57) ABSTRACT

A mounting apparatus for mounting a data storage device with an attached sliding member, includes a bracket and a locking member. The bracket includes a side plate which defines a sliding groove corresponding to the sliding member of the data storage device. The locking member is attached to the side plate. The locking member includes an elastic piece. A blocking piece is connected to the elastic piece. A distal end of the blocking piece is located in the sliding groove. The sliding member slides in the sliding groove, and pulls the elastic piece to deform until the sliding member slides over the blocking piece. The elastic piece rebounds to have the blocking piece restrict the sliding member in the sliding groove.

### BACKGROUND

1. Technical Field

The present disclosure relates to a mounting mechanism for storage devices, and more particularly to a mounting apparatus which facilitates attachment of a data storage device to a computer chassis.

2. Description of Related Art

Computers are widely used in modern life. It is desirable for a user or technician to conveniently access internal devices of the computers, such as storage devices, expansion cards and motherboards for servicing. However, storage devices, such as hard disk drives, compact disk read-only memory (CD-ROM) drives, digital video disc (DVD) drives, floppy disk drives, for example, are typically secured in a computer chassis with screws or bolts. It may be difficult and time-consuming to manipulate the screws or bolts to remove the storage device.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of a mounting apparatus for storage devices of an embodiment.

FIG. 2 is similar to FIG. 1, but viewed from another aspect.

FIG. 3 is a partially assembled view of the mounting apparatus of FIG. 1.

FIG. 4 is an assembled view of the mounting apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

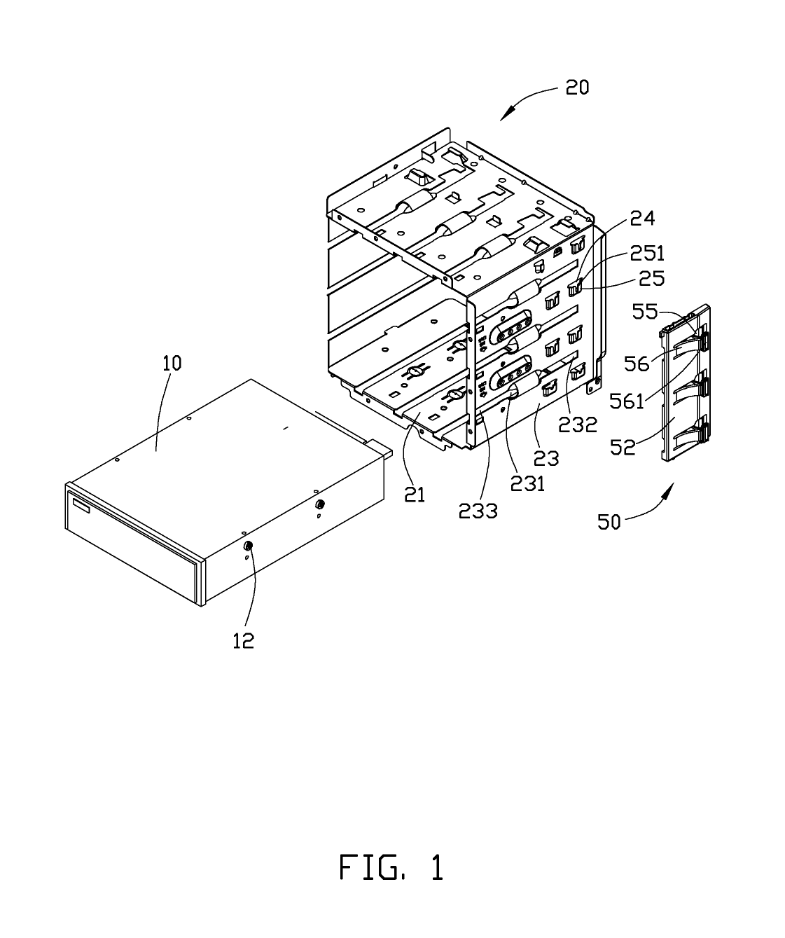

FIG. 1, is a mounting apparatus for mounting a data storage device 10 including a bracket 20 and a locking member 50. A pair of sliding members 12 are mounted on each of the opposite sides of the data storage device 10.

The bracket 20 includes a bottom plate 21 and a pair of side plates 23 perpendicularly connected to opposite edges of the bottom plate 21. Each of the pair of side plates 23 defines a plurality of parallel sliding grooves 231. Each of the plurality of sliding grooves 231 has a first end 232 and a second end 233. The second end 233 is located on an edge of corresponding one of the pair of side plates 23. The first end 232 is located in the corresponding one of the pair of side plates 23. A plurality of engaging pieces 25 protrude from each of the pair of side plates 23. Each of the plurality of engaging pieces 25 is located adjacent the first end 232 of each of the plurality of sliding grooves 231. Each of the pair of side plates 23 defines a cutout 24 aligned to each of the plurality of engaging pieces 25. Each of the plurality of engaging pieces 25 defines an engaging aperture 251 which interconnects to the cutout 24. The engaging aperture 251 is situated in a vertical direction.

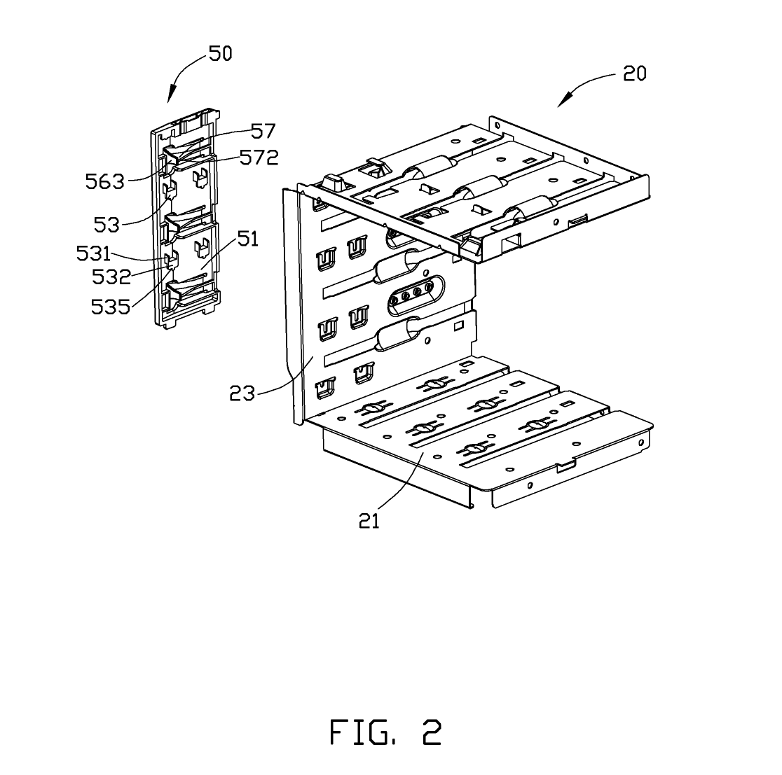

FIGS. 1 and 2, show the locking member 50 is a rectangular piece. The locking member 50 includes a first side 51 and a second side 52 which is opposite to the first side 51. The first side 51 faces each of the pair of side plates 23. A plurality of clasps 53 are located on the first side 51 corresponding to the plurality of engaging pieces 25. Each of the plurality of clasps 53 includes a pair of arms 531 which is connected to the first side 51. A suspending piece 532 is connected to the pair of arms 531. An inserting portion 535 is connected to a bottom edge of the suspending piece 532. The suspending piece 532 is parallel to the first side 51. A width of the inserting portion 535 is smaller than the width of the engaging aperture 251.

The locking member 50 defines a plurality of openings 55 corresponding to the plurality of sliding grooves 231 of each of the pair of side plates 23. An elastic piece 56 is connected to an edge of each of the plurality of openings 55. The elastic piece 56 has a free end which is tilted away from the second side 52. A blocking piece 563 is connected to the free end of the elastic piece 56. The blocking piece 563 extends through each of the plurality of openings 55 from the second side 52 and protrudes over the first side 51. A guiding piece 57 is connected between the blocking piece 563 and the elastic piece 56 and formed substantially in a triangle. The guiding piece 57 comprises a guiding surface 572, which extends from the elastic piece 56 to the blocking piece 563. The guiding surface 572 is an arc.

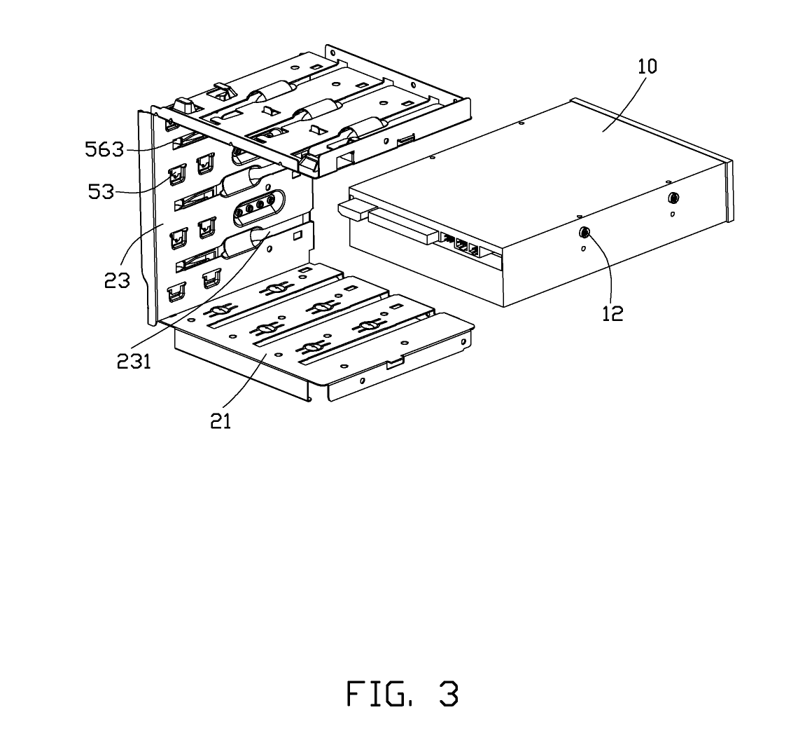

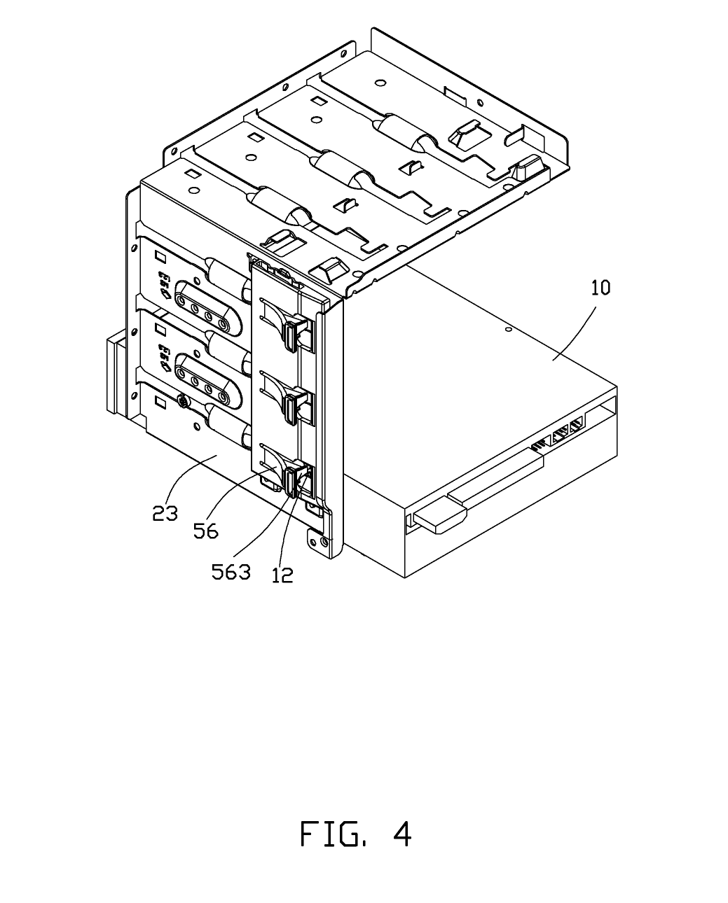

FIGS. 1 to 4, show in assembly, the first side 51 of the locking member 50 is moved towards each of the pair of side plates 23. The inserting portion 535 is inserted in the engaging aperture 251. The suspending piece 532 is inserted in the cutout 24. The suspending piece 532 slides along each of the plurality of engaging pieces 25 until each of the pair of arms 531 abuts a top edge of each of the plurality of engaging pieces 25. Therefore, the locking member 50 is mounted on each of the pair of side plates 23. In this position, a distal end of the blocking piece 563 of the locking member 50 is located in the first end 232 of each of the plurality of sliding grooves 231. The guiding surface 572 faces the plurality of sliding grooves 231.

The data storage device 10 is then located in the bracket 20 with each of the pair of sliding members 12 sliding in each of the plurality of sliding grooves 231 from the second end 233. Each of the pair of sliding members 12 slides in each of the plurality of sliding grooves 231 abutting the guiding surface 572. The elastic piece 56 is pulled and elastically bent by each of the pair of sliding members 12. Each of the pair of sliding members 12 slides along the guiding surface 572 until sliding over the blocking piece 563. In this position, each of the pair of sliding members 12 is located in the first end 232 of each of the plurality of sliding grooves 231. The elastic piece 56 rebounds to restrict each of the pair of sliding members 12 from moving out of the first end 232. Therefore, the data storage device 10 is mounted in the bracket 20.

To disassemble the data storage device 10 from the bracket 20, the elastic piece 56 is elastically bend so the blocking piece 563 does not restrict each of the pair of sliding members 12. Then, the data storage device 10 can be detached from the bracket 20.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A mounting apparatus for mounting a data storage device, comprising:
a sliding member attached on a data storage device;
a bracket comprising a side plate, the side plate defining a sliding groove corresponding to the sliding member of the data storage device; and
a locking member attached to the side plate, the locking member comprising an elastic piece, a blocking piece connected to the elastic piece, and a distal end of the blocking piece located in the sliding groove;
wherein the sliding member is adapted to slide in the sliding groove, and pull the elastic piece to elastically deform the elastic piece until the sliding member slides over the blocking piece, and the elastic piece is adapted to rebound to have the blocking piece restrict the sliding member in the sliding groove.

2. The mounting apparatus of claim 1, wherein the side plate comprises an engaging piece protruded thereon, the side plate defines a cutout aligned to the engaging piece; the locking member comprise a suspending piece, and the suspending piece is received in the cutout to engage with the engaging piece.

3. The mounting apparatus of claim 2, wherein the engaging piece defines an engaging aperture, the suspending piece comprises an inserting portion, and the inserting portion is located in the engaging aperture.

4. The mounting apparatus of claim 2, wherein the suspending piece is connected to the locking member via a pair of arms, the suspending piece is parallel to the locking member, and each of the pair of arms abuts a top edge of the engaging piece.

5. The mounting apparatus of claim 1, wherein the locking member comprises a first side and a second side opposite to the first side, the first side faces the side plate, the locking member defines an opening, the elastic piece is connected to an edge of the opening, and the elastic piece has a free end tilted away from the second side.

6. The mounting apparatus of claim 5, wherein the blocking piece is connected to the free end of the elastic piece, and the blocking piece extends through the opening from the second side and protrudes over the first side.

7. The mounting apparatus of claim 6, wherein a guiding piece is connected between the blocking piece and the elastic piece, the guiding piece comprises a guiding surface extending from the elastic piece to the blocking piece, and the guiding surface is configured to guide the sliding member to slide over the blocking piece.

8. The mounting apparatus of claim 7, wherein the guiding piece is triangularly shaped, and the guiding surface is arc shaped.

9. The mounting apparatus of claim 1, wherein the sliding groove comprises a first end and a second end, the second end is located on an edge of the side plate, the first end is located in the side plate, and a distal end of the blocking piece is located in the first end.

10. A mounting assembly, comprising:
a data storage device comprising a sliding member mounted thereon;
a bracket adapted to receive the data storage device located therein, the bracket comprising a side plate, the side plate defining a sliding groove; and
a locking member attached to the side plate, the locking member comprising an elastic piece, the elastic piece comprising a free end, a blocking piece connected to the free end, a guiding surface extending from the elastic piece to the blocking piece, a distal end of the blocking piece located in the sliding groove, and the guiding surface facing the sliding groove;
wherein the sliding member is adapted to slide in the sliding groove, pull the elastic piece to elastically deform the elastic piece, and be guided by the guiding surface to slide over the blocking piece, and the elastic piece is adapted to rebound so that the blocking piece restricts the sliding member in the sliding groove.

11. The mounting assembly of claim 10, wherein the side plate comprises an engaging piece protruded thereon, the side plate defines a cutout aligned to the engaging piece; the locking member comprise a suspending piece, and the suspending piece is received in the cutout to engage with the engaging piece.

12. The mounting assembly of claim 11, wherein the engaging piece defines an engaging aperture, the suspending piece comprises an inserting portion, and the inserting portion is located in the engaging aperture.

13. The mounting assembly of claim 11, wherein the suspending piece is connected to the locking member via a pair of arms, the suspending piece is parallel to the locking member, and each of the pair of arms abuts a top edge of the engaging piece.

14. The mounting assembly of claim 10, wherein the locking member comprises a first side and a second side opposite to the first side, the first side faces to the side plate, the locking member defines an opening, the elastic piece is connected to an edge of the opening, and the free end is tilted away from the second side.

15. The mounting assembly of claim 14, wherein the blocking piece extends through the opening from the second side and protrudes over the first side.

16. The mounting assembly of claim 15, wherein a guiding piece is connected between the blocking piece and the elastic piece, and the guiding surface is located on the guiding piece.

17. The mounting assembly of claim 16, wherein the guiding piece is triangularly shaped, and the guiding surface is arc shaped.

18. The mounting assembly of claim 10, wherein the sliding groove comprises a first end and a second end, the second end is located on an edge of the side plate, the first end is located in the side plate, and a distal end of the blocking piece is located in the first end.
